(19) United States
(12) Patent Application Publication
(10) Pub. No.: US 2010/0033517 A1
(43) Pub. Date: Feb. 11, 2010

(54) BI-STABLE DISPLAY AND DRIVING METHOD THEREOF

(76) Inventors: Kuan-Jui HO, Tainan City (TW); Ching-Ian Chao, Hsinchu County (TW); Chun-Te Lu, Hsinchu City (TW)

Correspondence Address: BIRCH STEWART KOLASCH & BIRCH, PO BOX 747, FALLS CHURCH, VA, 22040-0747, US

(21) Appl. No.: 12/579,819

(22) Filed: Oct. 15, 2009

Related U.S. Application Data
(63) Continuation-in-part of application No. 11/280,343, filed on Nov. 17, 2005.

(30) Foreign Application Priority Data
Nov. 18, 2004 (TW) 93135371

(51) Int. Cl. G09G 5/10; G09G 3/32

(52) U.S. Cl. 345/690; 345/82

(57) ABSTRACT

A bi-stable display having a plurality of bi-stable light emitting diodes (LEDs) and a driver are provided. The bi-stable LEDs have bi-stable memory characteristics and emit light according to a plurality of specified voltages, wherein the driver is used to apply the specified voltages to the bi-stable LEDs. The driver further has a brightness controller. The brightness controller is used to control the brightness of the bi-stable display by controlling a plurality of durations in which the specified voltages are applied to the bi-stable LEDs for a plurality of frames.

### CROSS REFERENCE TO RELATED APPLICATIONS

This application is a Continuation-In-Part of pending U.S. patent application Ser. No. 11/280,343, filed on Nov. 17, 2005, and entitled “bi-stable display and driving method thereof”.

### TECHNICAL FIELD

The invention relates to a bi-stable display, and in particular, to a bi-stable display and a driving method thereof.

### BACKGROUND

A passive panel display, having a simple structure, is easy to be designed and manufactured. For a passive panel display, every scan line in the passive panel is turned on sequentially. When a scan line is turned on, the pixels on the scan line emit light according to the intensity of currents applied thereto. To attain averaging brightness of the display, it is necessary for the pixels in a scan line to be driven by short pulses with high operating voltage and current, which significantly shortens the operating lifespan and degrades the emission efficiency of the display.

Unlike the passive panel display, an active panel display has memory capability to retain image information written into pixels therein. In the active panel display, the brightness of each pixel is controlled according to the image information stored, which enables the active panel display to require lower voltages and currents than the passive panel display. Therefore, the active panel display consumes lower power and has a longer operating lifespan when compared to passive panel displays. However, manufacturing of the active panel displays is more difficult than passive panel displays.

In January, 2002, Yang disclosed an organic bi-stable device (OBD) in Applied Physics Letters, Vol. 80, No. 3, P. 362. The OBD has bi-stable memory characteristics. FIG. 1 shows the bi-stable memory characteristics of the OBD of Yang. The horizontal axis is an operating voltage and the vertical axis is a corresponding current. Initially, the operating voltage is about 0V and the corresponding current is low (in an off-state). Then, the corresponding current increases with the operating voltage. In a writing operation, when a writing voltage is smaller than the threshold voltage Vth of the OBD, the corresponding current is kept at an off-state, and when the writing voltage is greater than a threshold voltage Vth, the corresponding current increases abruptly and then stays at an on-state, as shown in curve I. Thus, as shown in curve II, despite decreasing an operating voltage, once an operating voltage of the the OBD exceeds a threshold voltage Vth, an on-state of a corresponding current will remain activated. In a reading operation, a reading voltage lower than the threshold voltage Vth is applied to the pixels to display a memorized state. The corresponding current will be low if an anterior writing voltage has not exceeded a threshold voltage Vth. Meanwhile, the corresponding current will be high if an anterior writing voltage has exceeded a threshold voltage Vth. The OBD is capable of recording a previous operating state. In addition, the OBD will not return to an initial off-state until a large enough reverse biased voltage is provided. In an erasing operating, an erasing voltage will be reversed-biased to a reverse threshold voltage (not shown) to erase the previous on-state and turn the OBD to an off-state.

### SUMMARY

According to one embodiment, a bi-stable display comprises a plurality of bi-stable light emitting diodes (LEDs) and a driver. The bi-stable LEDs have bi-stable memory characteristics and emit light according to a plurality of specified voltages. The driver is used to apply the specified voltages to the bi-stable LEDs. The driver further comprises a brightness controller. The brightness controller is used to control the brightness of the bi-stable display by controlling a plurality of durations in which the specified voltages are applied to the bi-stable LEDs for a plurality of frames

According to another embodiment, a bi-stable display driving method comprises: applying a plurality of specified voltages to a plurality of bi-stable LEDs of a bi-stable display, wherein the bi-stable LEDs have bi-stable memory characteristics and emit light according to the specified voltages; and controlling a plurality of durations in which the specified voltages are applied to the bi-stable LEDs for a plurality of frames for controlling the brightness of the bi-stable display. A detailed description is given in the following embodiments with reference to the accompanying drawings.

### BRIEF DESCRIPTION OF DRAWINGS

The present invention can be more fully understood by reading the subsequent detailed description and examples with references made to the accompanying drawings, wherein:

FIG. 1 shows the bi-stable memory characteristics of an organic bi-stable device;

FIG. 2 shows the bi-stable memory characteristic of an organic light emitting diode;

FIG. 3 is a bi-stable display according to one embodiment;

FIG. 4A illustrates one of the frames applied to light emitting diode 330 according to one embodiment;

FIG. 4B illustrates one of the frames applied to light emitting diode 330 according to another embodiment;

FIG. 5 shows a flow chart of the bi-stable display driving method according to one embodiment.

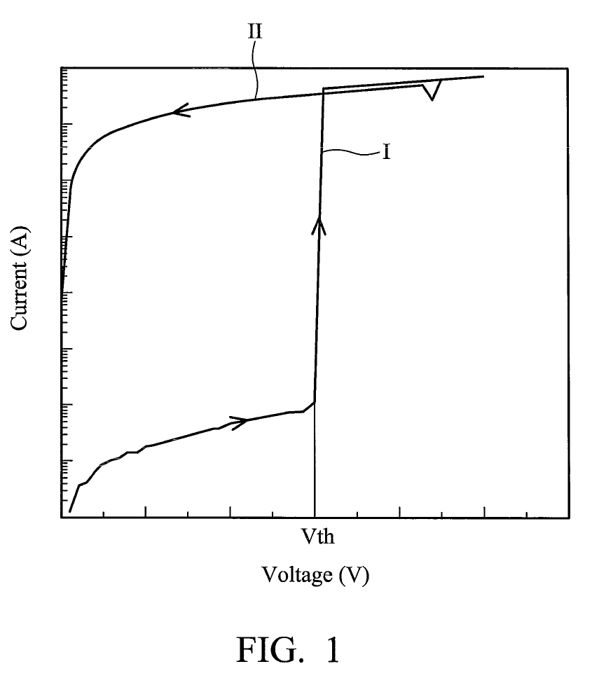

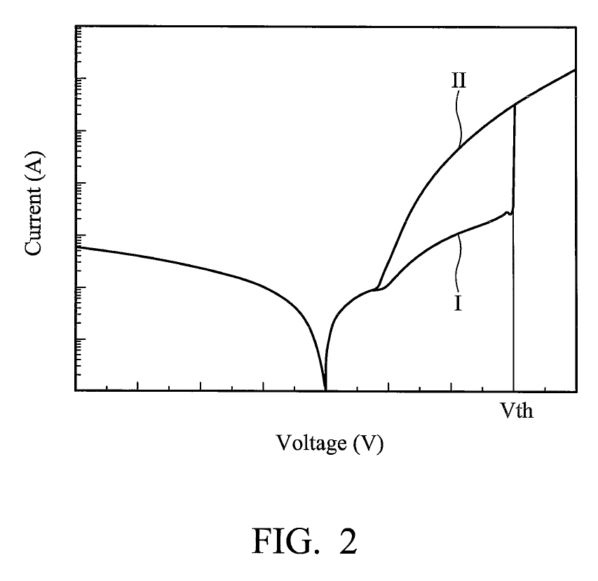

### DETAILED DESCRIPTION

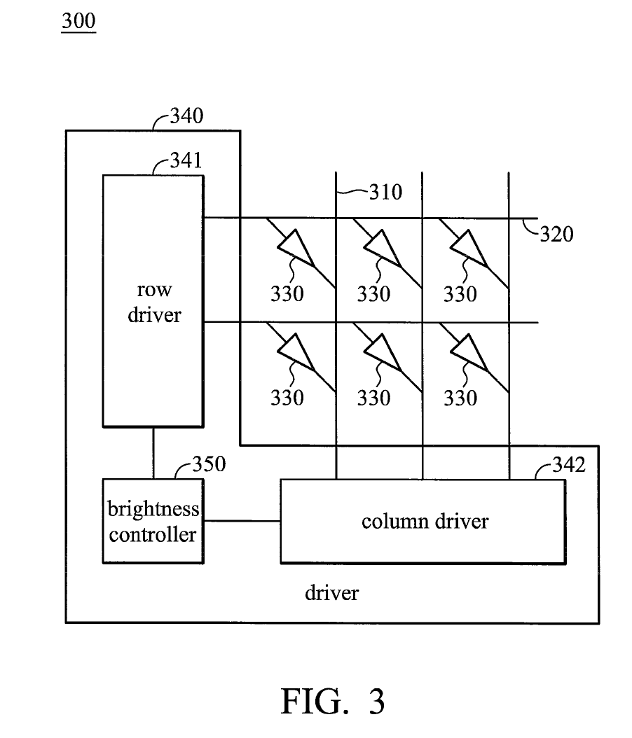

FIG. 3 is a bi-stable display according to one embodiment. The bi-stable display 300 comprises an array of a plurality of bi-stable light emitting diodes (LEDs) 330 and a plurality of row circuits 310 of the array, a plurality of column circuits 320 of the array, and a driver module 340. Each of the bi-stable LEDs 330 is electrically coupled between a row circuit 310 and a column circuit 320. In the embodiment, the anode of the bi-stable LEDs 330 is electrically coupled to the row circuit 310, and the cathode of the bi-stable LEDs 330 is electrically coupled to the column circuit 320. In one embodiment, all the column circuits may be provided with a same source, and all the row circuits are provided with another same source, wherein the first source and the second source are changed at different phases of a specified voltage, which will be discussed as follows.

The bi-stable LEDs 330 are provided with bi-stable memory characteristics. As described in the related art, each of the bi-stable LEDs 330 comprises a threshold voltage and a reverse threshold voltage. The bi-stable LEDs 330 are in the off-state when the specified voltages are not forward-biased to the threshold voltage, turned to an on-state when the specified voltages are forward-biased to the threshold voltage; and turned to an off-state when the specified voltages are reverse-biased to the reverse threshold voltage. Note that as an example, the bi-stable LEDs 330 may be organic bi-stable light emitting devices (OBLEDs), but are not limited thereto.

In an embodiment, the driver module 340 comprises the row driver 341 and the column driver 342. In the bi-stable display 300, each row circuit 310 is coupled to a row driver 341, while each column circuit 320 is coupled to a column driver 342. The driver 340 is used to apply a plurality of specified voltages to the bi-stable LEDs 330 to operate the bi-stable LEDs 330 in various states. Specifically, the specified voltage may be the voltage difference between a row 310 and a column 320. A pixel of the display 300 is used to emit light according to the specified voltage applied thereto. Each of the row driver 341 or the column driver 342 respectively has at least three states which are low state (for example, 0V), high state (for example, Vw), and high impedance state (high output impedance in a digital circuit; referred to as HiZ) to turn on or off the bi-stable LEDs 330.

In this embodiment, a stable display 300 comprising the bi-stable LEDs 330 may be operated in three modes: a writing mode, a reading mode, and an erasing mode. In the writing mode, the specified voltage is a writing voltage Vw for forward-biasing the bi-stable LEDs 330 and is greater than the threshold voltage Vth of the bi-stable LEDs 330. In the reading mode, the specified voltage is a reading voltage Vr for forward-biasing the bi-stable LEDs 330 and is smaller than the threshold voltage Vth of the bi-stable LEDs 330. In the erasing mode, the specified voltage is an erasing voltage Ve for reverse-biasing the bi-stable LEDs 330 and the absolute value of the erasing voltage Ve is greater than the reverse threshold voltage Vrth. For example, when it is assumed that the threshold voltage Vth of the bi-stable LEDs 330 is 6 volts and the reverse threshold voltage Vrth of the bi-stable LEDs 330 is −6 volt, the writing voltage Vw, the reading voltage Vr, and the erasing voltage Ve may be respectively 7 volt, 5 volts and −7 volt. Since the 7 volts of the writing voltage Vw is greater than the 6 volts of the threshold voltage Vth, the bi-stable LEDs 330 will be forward-biased to the on-state. Since the 5 volts of the reading voltage Vr is not greater than the 6 volts of the threshold voltage Vth, the reading voltage Vr does not change the state of the bi-stable LEDs 330 and displays the state previously set by the writing voltage Vw. Since the absolute value of the −7 volts of the erasing voltage Ve is greater than that of the −6 volts of the reverse threshold voltage Vrth, the bi-stable LEDs 330 will be reversed-biased and turned to the off-state.

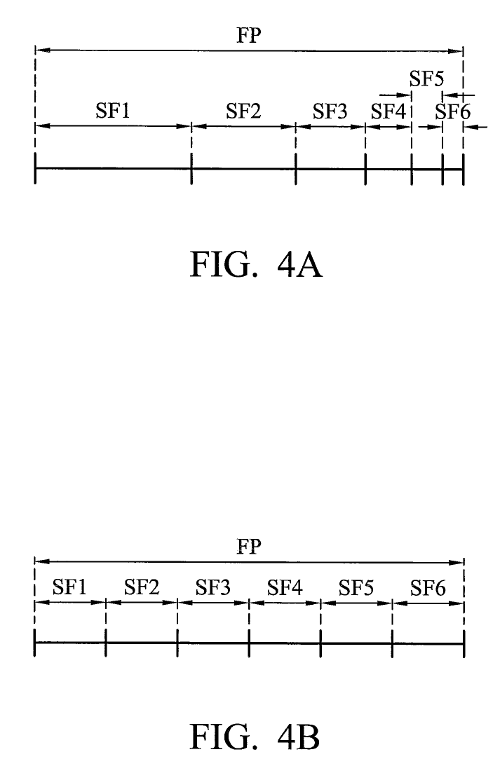

In order to achieve and improve brightness control, the driver 340 of the display 300 further comprises a brightness controller 350. The brightness controller 350 controls the brightness of the bi-stable display 300 by controlling the durations in which the specified voltages are applied to the bi-stable LEDs 330 of the bi-stable display 300 for a plurality of frames. FIG. 4A illustrates one of the frames applied to light emitting diode 330 according to one embodiment. A frame of an image of a display may last for a short duration. For example, the display 300 may have a frame rate of 24 frames per second (24FPS). In this embodiment, the frame FP comprises a plurality of sub-frames SF1˜SF6, and each of the sub-frames SF1˜SF6 have different duration. The sequence of the durations of each sub-frame in each frame may be a geometric sequence, For example, the duration of the sub-frame SF1 may be half of the total duration of the frame FP, the duration of the sub-frame SF2 may be one-fourth of the total duration of the frame FP, the duration of the sub-frame SF3 may be one-eighth of the total duration of the frame FP and so on. In each of the sub-frames SF1˜SF6, the writing mode, reading mode, and erasing mode may be sequentially implemented to turn on or off the bi-stable LED. For a viewer or a sensor, a frame lasts for a short duration; therefore the brightness of a frame may be regarded as the total of the brightness of all the sub-frames in the frame. In this case, for the six sub-frames in the frame, a 64 level grayscale image is achieved. Thus, the brightness of the bi-stable LED 330 may be varied and controlled to be a 64 level grayscale image. FIG. 4B illustrates one of the frames of operated by light emitting diodes 330 according to another embodiment. In this embodiment, the frame FP may comprise a plurality of sub-frames SF1˜SF6 and each of the sub-frames SF1˜SF6 have the same duration. Since the sub-frames SF1˜SF6 of FIG. 4B are also respectively turned on or off to vary the brightness of the bi-stable LEDs 300 as in FIG. 4A, detailed description will be emitted for brevity.

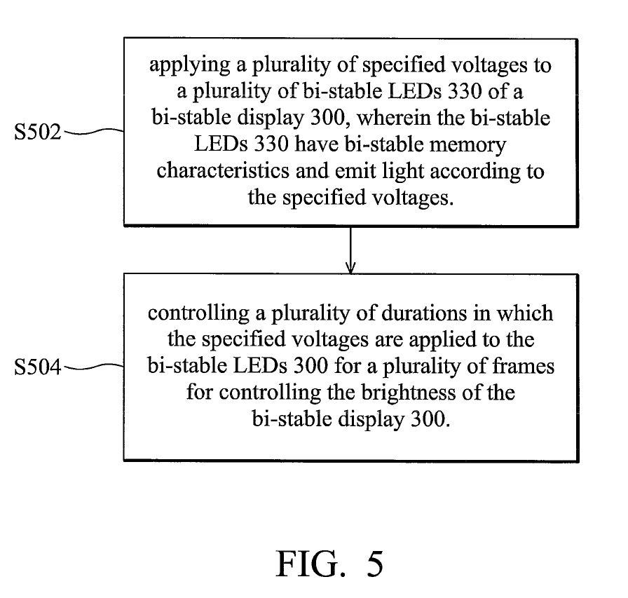

FIG. 5 shows a flow chart of the bi-stable display driving method according to one embodiment. Please refer to FIG. 3 and FIG. 5. In step S502, the driver 340 applies a plurality of specified voltages to a plurality of bi-stable LEDs 330 of a bi-stable display 300, wherein the bi-stable LEDs 330 have bi-stable memory characteristics and emit light according to the specified voltages. Specifically, each of the bi-stable LEDs 330 comprises a threshold voltage Vth and a reverse threshold voltage Vrth. The bi-stable LEDs 330 are in an off-state when the specified voltages are not forward-biased to the threshold voltage Vth, turned to an on-state when the specified voltages are forward-biased to the threshold voltage Vth; and turned to an off-state when the specified voltages are reverse-biased to the reverse threshold voltage Vrth. The specified voltages comprise a writing voltage Vw, a reading voltage Vr, and an erasing voltage Ve. The writing voltage Vw may be forward-biased and greater than the threshold voltage Vth; the reading voltage Vr may be forward-biased and smaller than the threshold voltage Vth; and the erasing voltage Ve may be reverse-biased and greater than the reverse threshold voltage Vrth. Also, the writing voltage Vw may be forward-biased and greater than the threshold voltage Vth, the reading voltage Vr may be forward-biased and smaller than the threshold voltage Vth, and the erasing voltage Ve may be reverse-biased and greater than the reverse threshold voltage Vrth.

Next, in step S504, the brightness controller 350 in the driver 340 controls a plurality of durations in which the specified voltages are applied to the bi-stable LEDs 300 for a plurality of frames for controlling the brightness of the bi-stable display 300. Please refer to FIGS. 4A and 4B. In an embodiment, each of the frames comprises a plurality of sub-frames. In a frame, each of the sub-frames has different durations, and is respectively turned on or off to vary the brightness of the bi-stable LEDs 330. Moreover, the sequence of the durations of each sub-frame in each frame may be a geometric sequence. In another embodiment, each of the frames comprises a plurality of sub-frames. In a frame, each of the sub-frames has the same duration and is respectively turned on or off to vary the brightness of the bi-stable LEDs 330.

While the invention has been described by way of example and in terms of embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A bi-stable display, comprising:
a plurality of bi-stable light emitting diodes (LEDs), having bi-stable memory characteristics for emitting light according to a plurality of specified voltages; and
a driver for applying the specified voltages to the bi-stable LEDs, further comprising:
a brightness controller for controlling the brightness of the bi-stable display by controlling a plurality of durations in which the specified voltages are applied to the bi-stable LEDs for a plurality of frames.

2. The bi-stable display as claimed in claim 1, wherein each of the frames comprises a plurality of sub-frames, and each of the sub-frames has different durations and is respectively turned on or off to vary the brightness of the bi-stable LEDs.

3. The bi-stable display as claimed in claim 2, wherein the sequence of the durations of each sub-frame in each frame is a geometric sequence.

4. The bi-stable display as claimed in claim 1, wherein each of the frames comprises a plurality of sub-frames, and each of the sub-frames has the same duration and is respectively turned on or off to vary the brightness of the bi-stable LEDs.

5. The bi-stable display as claimed in claim 1, wherein each of the bi-stable LEDs comprise a threshold voltage and a reverse threshold voltage and the bi-stable LEDs are in an off-state when the specified voltages are not forward-biased to the threshold voltage, turned to an on-state when the specified voltages are forward-biased to the threshold voltage; and turned to an off-state when the specified voltages are reverse-biased to the reverse threshold voltage.

6. The bi-stable display as claimed in claim 5, wherein the specified voltages comprise a writing voltage, and the writing voltage is forward-biased and greater than the threshold voltage.

7. The bi-stable display as claimed in claim 5, wherein the specified voltages comprise a reading voltage, and the reading voltage is forward-biased and smaller than the threshold voltage.

8. The bi-stable display as claimed in claim 5, wherein the specified voltage comprises an erasing voltage, and the erasing voltage is reverse-biased and greater than the reverse threshold voltage.

9. The bi-stable display as claimed in claim 1, wherein the bi-stable display further comprises:
a plurality of column circuits; and
a plurality of row circuits;
wherein each of the bi-stable LED is coupled between one of the column circuits and one of the row circuits; and all the column circuits are provided with a same first source, and all the row circuits are provided with a same second source, wherein the first source and the second source are changed at different phases of the specified voltages.

10. A bi-stable display driving method, comprising:
applying a plurality of specified voltages to a plurality of bi-stable LEDs of a bi-stable display, wherein the bi-stable LEDs have bi-stable memory characteristics and emit light according to the specified voltages; and
controlling a plurality of durations in which the specified voltages are applied to the bi-stable LEDs for a plurality of frames for controlling the brightness of the bi-stable display.

11. The bi-stable display driving method as claimed in claim 10, wherein each of the frames comprises a plurality of sub-frames, and each of the sub-frames has different durations and is respectively turned on or off to vary the brightness of the bi-stable LEDs.

12. The bi-stable display driving method as claimed in claim 11, wherein the sequence of the durations of each sub-frame in each frame is a geometric sequence.

13. The bi-stable display driving method as claimed in claim 10, wherein each of the frames comprises a plurality of sub-frames, and each of the sub-frames has the same duration and is respectively turned on or off to vary the brightness of the bi-stable LEDs.

14. The bi-stable display driving method as claimed in claim 10, wherein each of the bi-stable LEDs comprise a threshold voltage and a reverse threshold voltage; and the bi-stable LEDs are in an off-state when the specified voltages are not forward-biased to the threshold voltage, turned to an on-state when the specified voltages are forward-biased to the threshold voltage; and turned to an off-state when the specified voltages are reverse-biased to the reverse threshold voltage.

15. The bi-stable display driving method as claimed in claim 14, wherein the specified voltages comprise a writing voltage, and the writing voltage is forward-biased and greater than the threshold voltage.

16. The bi-stable display driving method as claimed in claim 14, wherein the specified voltages comprise a reading voltage, and the reading voltage is forward-biased and smaller than the threshold voltage.

17. The bi-stable display driving method as claimed in claim 14, wherein the specified voltage comprises an erasing voltage, and the erasing voltage is reverse-biased and greater than the reverse threshold voltage.
